(19) United States
(12) Patent Application Publication
(10) Pub. No.: US 2017/0229497 A1
(43) Pub. Date: Aug. 10, 2017

(54) BACKSIDE ILLUMINATED IMAGE SENSOR AND METHOD OF MANUFACTURING THE SAME

(71) Applicant: DONGBU HITEK CO., LTD., Seoul (KR)

(72) Inventor: Chang Hun Han, Gyeonggi-do (KR)

(21) Appl. No.: 15/414,143

(22) Filed: Jan. 24, 2017

(30) Foreign Application Priority Data
Feb. 4, 2016 (KR) 1020160014179

(51) Int. Cl. H01L 27/146

(52) U.S. Cl. CPC H01L 27/1464; H01L 27/14627; H01L 27/14621; H01L 27/14687

(57) ABSTRACT

A backside illuminated image sensor includes a substrate having a frontside surface and a backside surface, a photodiode disposed in the substrate, an insulating layer disposed on the backside surface and a fixed charge layer disposed on the insulating layer. A charge accumulation region capable of being used as a backside pinning layer is formed between the photodiode and the backside surface of the substrate by the fixed charge layer.

### CROSS-REFERENCE TO RELATED APPLICATION

This application claims the priority benefit of Korean Patent Application No. 10-2016-0014179, filed on Feb. 4, 2016, and all the benefits accruing therefrom under 35 U.S.C. §119, the contents of which are incorporated by reference in their entirety.

### BACKGROUND

The present disclosure relates to a backside illuminated image sensor and a method of manufacturing the same.

In general, an image sensor is a semiconductor device that converts an optical image into electrical signals, and may be classified or categorized as a charge coupled device (CCD) or a CMOS Image Sensor (CIS).

The CIS includes unit pixels, each including a photodiode and MOS transistors. The CIS sequentially detects the electrical signals of the unit pixels using a switching method, thereby forming an image.

The CIS is made by forming photodiodes in or on a semiconductor substrate, forming transistors connected to the photodiodes on the semiconductor substrate, forming wiring layers functioning as signal lines connected to the transistors, and forming a color filter layer and micro lenses on or over the wiring layers.

Meanwhile, a backside illuminated image sensor may have an improved light-receiving efficiency in comparison with a frontside illuminated image sensor. The backside illuminated image sensor may include a wiring layers disposed on a frontside surface of a substrate, and a color filter layer and micro lenses disposed on a backside surface of the substrate.

Further, the backside illuminated image sensor may include a backside pinning layer disposed in a backside surface portion of the substrate so as to form a pinned photodiode. The backside pinning layer may be formed by an ion implantation process and then activated by a laser annealing process after performing a back-grinding process for reducing a thickness of the substrate.

### SUMMARY

The present disclosure provides a method of manufacturing a backside illuminated image sensor capable of omitting an ion implantation process and a laser annealing process for forming a backside pinning layer and a backside illuminated image sensor manufactured by the method.

In accordance with an aspect of the present disclosure, a backside illuminated image sensor may include a substrate having a frontside surface and a backside surface; a photodiode disposed in the substrate; an insulating layer disposed on the backside surface of the substrate; and a fixed charge layer disposed on the insulating layer.

In accordance with some exemplary embodiments, the backside illuminated image sensor may further include a high concentration impurity region disposed in the substrate and a gate electrode disposed on the frontside surface of the substrate between the photodiode and the high concentration impurity region.

In accordance with some exemplary embodiments, the substrate may have a first conductive type and the photodiode may have a second conductive type.

In accordance with some exemplary embodiments, the backside illuminated image sensor may further include a frontside pinning layer of the first conductive type disposed between the photodiode and the frontside surface of the substrate.

In accordance with some exemplary embodiments, the backside illuminated image sensor may further include a backside pinning layer of the first conductive type disposed between the photodiode and the backside surface of the substrate.

In accordance with another aspect of the present disclosure, a backside illuminated image sensor may include a substrate having a frontside surface and a backside surface; a p-type photodiode disposed in the substrate; an insulating layer disposed on the backside surface of the substrate; and a positive fixed charge layer disposed on the insulating layer.

In accordance with some exemplary embodiments, the backside illuminated image sensor may further include an n-type frontside pinning layer disposed between the p-type photodiode and the frontside surface of the substrate.

In accordance with some exemplary embodiments, the backside illuminated image sensor may further include an n-type backside pinning layer disposed between the p-type photodiode and the backside surface of the substrate.

In accordance with some exemplary embodiments, the backside illuminated image sensor may further include a p-type high concentration impurity region disposed in a frontside surface portion of the substrate to be spaced apart from the p-type photodiode; and a gate electrode disposed on the frontside surface of the substrate between the p-type photodiode and the p-type high concentration impurity region.

In accordance with some exemplary embodiments, the positive fixed charge layer may include zirconium oxide, hafnium silicon oxide, hafnium silicon oxynitride or silicon nitride.

In accordance with some exemplary embodiments, the backside illuminated image sensor may further include a second insulating layer disposed on the positive fixed charge layer and a light-blocking pattern disposed on the second insulating layer.

In accordance with some exemplary embodiments, the backside illuminated image sensor may further include a passivation layer disposed on the second insulating layer and the light-blocking pattern; a color filter layer disposed on the passivation layer; and a micro lens disposed on the color filter layer.

In accordance with still another aspect of the present disclosure, a method of manufacturing a backside illuminated image sensor may include forming a photodiode in a substrate having a frontside surface and a backside surface; forming an insulating layer on the backside surface of the substrate; and forming a fixed charge layer on the insulating layer.

In accordance with some exemplary embodiments, the method may further include forming a gate electrode on the frontside surface of the substrate; and forming a high concentration impurity region in the substrate, the gate electrode being disposed on the frontside surface of the substrate between the photodiode and the high concentration impurity region.

In accordance with some exemplary embodiments, the method may further include forming a frontside pinning layer between the photodiode and the frontside surface of the substrate.

In accordance with some exemplary embodiments, the substrate may have a first conductive type and the photodiode may have a second conductive type.

In accordance with some exemplary embodiments, the substrate may include an n-type epitaxial layer and the photodiode may include a p-type impurity region formed in the n-type epitaxial layer.

In accordance with some exemplary embodiments, the fixed charge layer may have a positive fixed charge.

In accordance with some exemplary embodiments, the fixed charge layer may include zirconium oxide, hafnium silicon oxide, hafnium silicon oxynitride or silicon nitride.

In accordance with some exemplary embodiments, the method may further include forming a backside pinning layer in the substrate; and removing a backside surface portion of the substrate by using a back-grinding process so as to expose a backside surface of the backside pinning layer. Particularly, the photodiode may be formed on a frontside surface of the backside pinning layer, and the insulating layer may be formed on the backside surface of the backside pinning layer.

The above summary is not intended to describe each illustrated embodiment or every implementation of the subject matter hereof. The figures and the detailed description that follow more particularly exemplify various embodiments.

### BRIEF DESCRIPTION OF THE DRAWINGS

Exemplary embodiments can be understood in more detail from the following description taken in conjunction with the accompanying drawings, in which:

FIG. 1 is a cross-sectional view illustrating a backside illuminated image sensor in accordance with an exemplary embodiment of the present disclosure;

FIG. 2 is a cross-sectional view illustrating a backside illuminated image sensor in accordance with another exemplary embodiment of the present disclosure;

FIGS. 3 to 7 are cross-sectional views illustrating a method of manufacturing the backside illuminated image sensor as shown in FIG. 1; and

FIG. 8 is a cross-sectional view illustrating a method of forming a backside pinning layer as shown in FIG. 2.

While various embodiments are amenable to various modifications and alternative forms, specifics thereof have been shown by way of example in the drawings and will be described in detail. It should be understood, however, that the intention is not to limit the claimed inventions to the particular embodiments described. On the contrary, the intention is to cover all modifications, equivalents, and alternatives falling within the spirit and scope of the subject matter as defined by the claims.

### DETAILED DESCRIPTION OF THE DRAWINGS

Hereinafter, embodiments of the present invention are described in more detail with reference to the accompanying drawings. However, the present invention is not limited to the embodiments described below and is implemented in various other forms. Embodiments below are not provided to completely disclose every possible embodiment of the present invention, but rather are provided to convey the range of the present invention to those skilled in the art by way of exemplary embodiments.

In the specification, when one component is referred to as being on or connected to another component or layer, it can be directly on or connected to the other component or layer, or an intervening component or layer may also be present. Unlike this, it will be understood that when one component is referred to as directly being directly on or directly connected to another component or layer, it means that no intervening component is present. Also, though terms like a first, a second, and a third are used to describe various regions and layers in various embodiments of the present invention, the regions and the layers are not limited to these terms.

Terminologies used below are used to merely describe specific embodiments, but do not limit the present invention. Additionally, unless otherwise defined here, all the terms including technical or scientific terms, may have the same meaning that is generally understood by those skilled in the art.

Embodiments of the present invention are described with reference to schematic drawings of ideal embodiments. Accordingly, changes in manufacturing methods and/or allowable errors may be expected from the forms of the drawings. Accordingly, embodiments of the present invention are not described being limited to the specific forms or areas in the drawings, and include the deviations of the forms. The areas may be entirely schematic, and their forms may not describe or depict accurate forms or structures in any given area, and are not intended to limit the scope of the present invention.

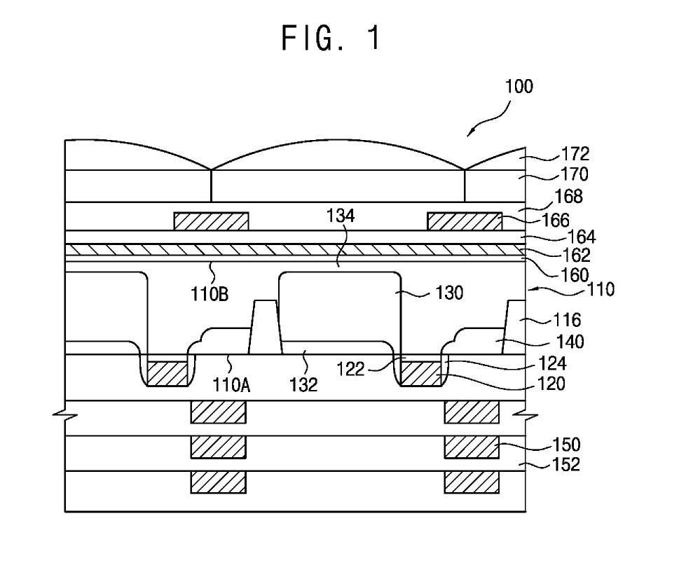

FIG. 1 is a cross-sectional view illustrating a backside illuminated image sensor in accordance with an exemplary embodiment of the present disclosure.

Referring to FIG. 1, in accordance with an exemplary embodiment of the present disclosure, a backside illuminated image sensor 100 may include a substrate 110 having a frontside surface 110A and a backside surface 110B, a photodiode 130 formed in the substrate 110, an insulating layer 160 formed on the backside surface 110B of the substrate 110, and a fixed charge layer 162 formed on the insulating layer 160. Further, the backside illuminated image sensor 100 may include device isolation regions 116 formed in the substrate 110 adjacent the frontside surface 110A.

The substrate 110 may have a first conductive type, and the photodiode 130 may have a second conductive type. For example, an n-type substrate may be used as the substrate 110, and the photodiode may be a p-type impurity region formed in the substrate 110. The photodiode 130 may be used to accumulate holes generated in the substrate 110 by the incident photons.

The insulating layer 160 may include silicon oxide (SiO₂) or silicon oxynitride (SiON). The fixed charge layer 162 may form a charge accumulation region 134 in a backside surface portion of the substrate 110, and the charge accumulation region 134 may be used as a backside pinning layer.

For example, the fixed charge layer 162 may be a positive fixed charge layer having positive charges. In such case, an electron accumulation layer 134 may be formed by the positive fixed charge layer 162 in the backside surface portion of the substrate 110, that is, between the photodiode 130 and the backside surface 110B of the substrate 110 or underneath the backside surface 110B of the substrate 110, and the electron accumulation layer 134 may be used as an n-type backside pinning layer. In detail, the positive charges of the fixed charge layer 162 may form a negatively charged, shallow minority carrier rich region in the backside surface portion of the substrate 110, which may function as the n-type backside pinning layer. For example, the fixed charge layer 162 may include zirconium oxide (ZrO₂), hafnium silicon oxide (HfSiO₂), hafnium silicon oxynitride (HfSiON) or silicon nitride (Si₃N₄).

Alternatively, when the substrate 110 has the second conductive type and the photodiode 130 has the first conductive type, that is, a p-type substrate is used as the substrate 110 and the photodiode 130 includes an n-type impurity region, the fixed charge layer 162 may be a negative fixed charge layer, and a hole accumulation region 134 capable of being used as a p-type backside pinning layer may be created in the backside surface portion of the substrate 110. For example, the negative fixed charge layer may include hafnium oxide (HfO₂), hafnium oxynitride (HfON), aluminum oxide (Al₂O₃), aluminum oxynitride (AlON), hafnium aluminum oxide (HfAlO) or hafnium aluminum oxynitride (HfAlON).

As a result, an ion implantation process for forming a conventionally used backside pinning layer and a laser annealing process for activating the backside pinning layer may be omitted, and the photodiode 130 can be larger, for example, closer to the backside surface 110B of the substrate 110 and as deep therein as allowable considering cross-talk behavior, for improved fill factor.

Further, problems with the accidental or unintended implanting of dopants into the photodiode 130 associated with tail distribution of the implant profile can be overcome since no implant is performed above the photodiode 130, and thus the fill factor of the photodiode 130 may also be improved.

A frontside pinning layer 132 having the first conductive type may be formed in a frontside surface portion of the substrate 110, that is, between the photodiode 130 and the frontside surface 110A of the substrate 110. For example, when a p-type photodiode 130 is used, an n-type frontside pinning layer 132 may be formed in the frontside surface 110A portion of the substrate 110, which may be an n-type high concentration impurity region.

Further, a high concentration impurity region 140 may be formed in a frontside surface portion of the substrate 110, and a gate electrode 120 may be formed on the frontside surface 110A of the substrate 110. A gate insulating layer 122 may be formed between the frontside surface 110A of the substrate 110 and the gate electrode 120. The high concentration impurity region 140 may be disposed apart from the photodiode 130, and the gate electrode 120 may be disposed on the frontside surface 110A of the substrate 110 between the photodiode 130 and the high concentration impurity region 140.

For example, a p-type high concentration impurity region 140 may be formed in the frontside surface 110A portion of the substrate 110. The high concentration impurity region 140 may be used as a floating diffusion region if the backside illuminated image sensor 100 is a 4T (or more than four transistors) layout or an active region for connecting the photodiode 130 with a reset circuitry if the backside illuminated image sensor 100 is a 3T (or fewer than three transistors) layout.

A second insulating layer 164 may be formed on the fixed charge layer 162, and a light-blocking pattern 166 may be formed on the second insulating layer 164. The light-blocking pattern 166 may be used to reduce the cross-talk of the backside illuminated image sensor 100. For example, the second insulating layer 164 may include a light-receiving region (i.e., the portion not occluded by light-blocking pattern 166) corresponding to the photodiode 130 and a light-blocking region surrounding the light-receiving region, and the light-blocking pattern 166 may be formed on the light-blocking region.

A passivation layer 168 may be formed on and around the second insulating layer 164 and the light-blocking pattern 166, and a color filter layer 170 and micro lenses 172 may be formed on the passivation layer 168.

Wiring layers 150 electrically connected with the photodiode 130 and interlayer insulating layers 152 for electrically isolating the wiring layers 150 from one another may be formed on the frontside surface 110A of the substrate 110. The wiring layers 150 may be made of aluminum (Al), copper (Cu), and the like, and the interlayer insulating layers 152 may be made of silicon oxide (SiO₂) or other insulating or substantially undoped semiconductor material.

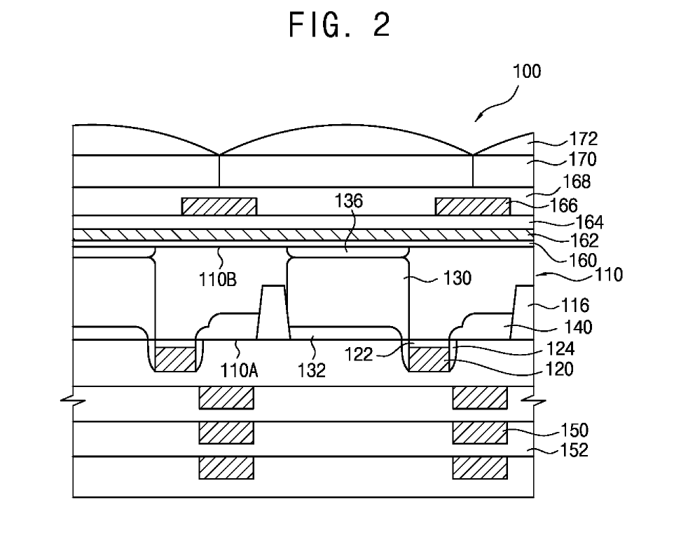

FIG. 2 is a cross-sectional view illustrating a backside illuminated image sensor in accordance with another exemplary embodiment of the present disclosure.

Referring to FIG. 2, a backside pinning layer 136 having the first conductive type may be formed between the photodiode 130 and the backside surface 110B of the substrate 110. For example, the backside pinning layer 136 may be an n-type high concentration impurity region. In such case, electrons may be accumulated in the backside pinning layer 136 by the fixed charge layer 162, and the backside pinning layer 136 may thus be significantly enhanced. Particularly, the backside pinning layer 136 may be formed prior to the photodiode 130 and may be activated by a rapid thermal process.

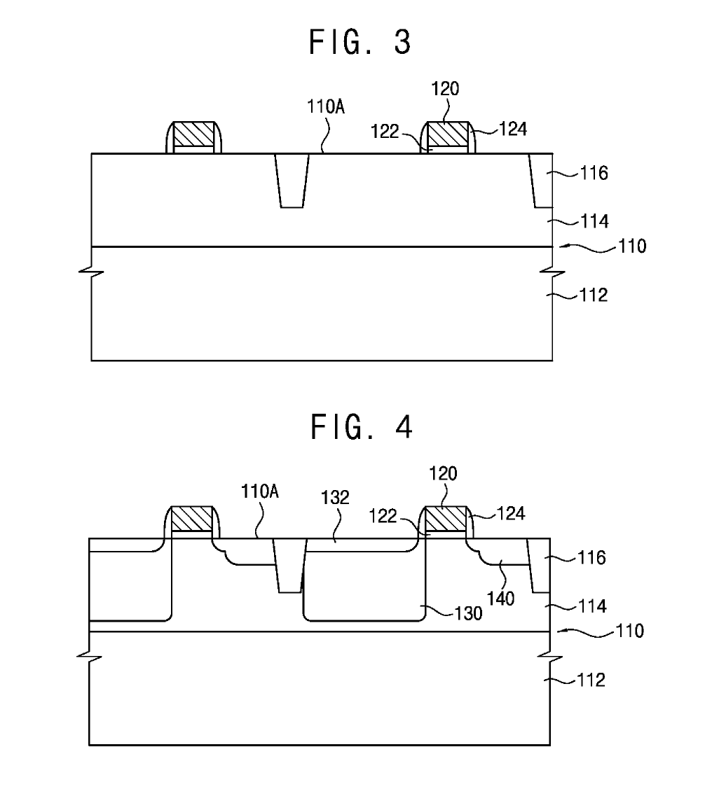

FIGS. 3 to 7 are cross-sectional views illustrating a method of manufacturing the backside illuminated image sensor as shown in FIG. 1.

Referring to FIG. 3, device isolation regions 116 may be formed in frontside surface portions of a substrate 110 in order to define an active region. The substrate 110 may include a bulk silicon substrate 112 and an epitaxial layer 114 formed thereon. For example, an epitaxial layer 114 of a first conductive type, e.g., an n-type, may be formed on the substrate 110. Alternatively, an n-type substrate may be used as the substrate 110. In such case, the epitaxial layer 114 may be omitted. Meanwhile, the device isolation regions 116 may be formed by a shallow trench isolation (STI) process.

A gate insulating layer 122 and a gate electrode 120 may be formed on the active region of the substrate 110, and gate spacers 124 may be formed on side surfaces of the gate electrode 120. The gate electrode 120 may be used as a transfer gate in a case of a 4T layout or a reset gate in a case of a 3T layout. Further, though not shown in figures, a source follower gate electrode and a select gate electrode may be simultaneously formed with the gate electrode 120 on the substrate 110.

Referring to FIG. 4, a photodiode 130 having a second conductive type may be formed in the substrate 110. For example, a p-type photodiode 130 may be formed in the n-type epitaxial layer 114. Particularly, the p-type photodiode 130 may be a p-type impurity region formed by an ion implantation process.

A frontside pinning layer 132 of the first conductive type may be formed between the photodiode 130 and the frontside surface 110A of the substrate 110. For example, an n-type frontside pinning layer 132 may be formed on the p-type photodiode 130. Particularly, the n-type frontside pinning layer 132 may be an n-type high concentration impurity region formed by an ion implantation process. The photodiode 130 and the frontside pinning layer 132 may be activated by a rapid thermal process.

A high concentration impurity region 140 may be formed in a frontside surface portion of the substrate 110 to be spaced apart from the photodiode 130. For example, a p-type high concentration impurity region 140 may be formed in the frontside surface portion of the substrate 110 to be laterally spaced apart from the p-type photodiode 130. The high concentration impurity region 140 may be used as a floating diffusion region in a case of a 4T layout or an active region for connecting the photodiode 130 with a reset circuitry in a case of a 3T layout.

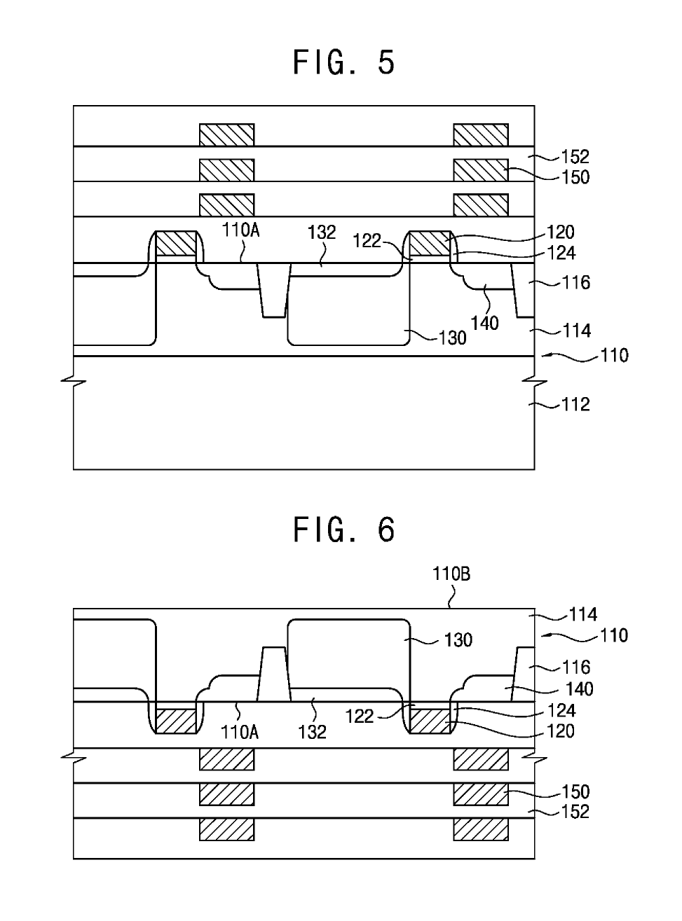

Referring to FIG. 5, wiring layers 150 electrically connected with the photodiode 130 and interlayer insulating layers 152 for electrically isolating the wiring layers 150 from one another may be formed on the frontside surface 110A of the substrate 110. The wiring layers 150 may be made of aluminum (Al), copper (Cu), and the like, and the interlayer insulating layers 152 may be made of silicon oxide (SiO₂).

Referring to FIG. 6, a back-grinding process, e.g., a chemical and/or mechanical polishing or etching process may be performed in order to reduce a thickness of the substrate 110. For example, the bulk silicon substrate 112 may be removed by the back-grinding process. After performing the back-grinding process, a wet etching process may be performed to remove contaminants from the backside surface 110B of the substrate 110.

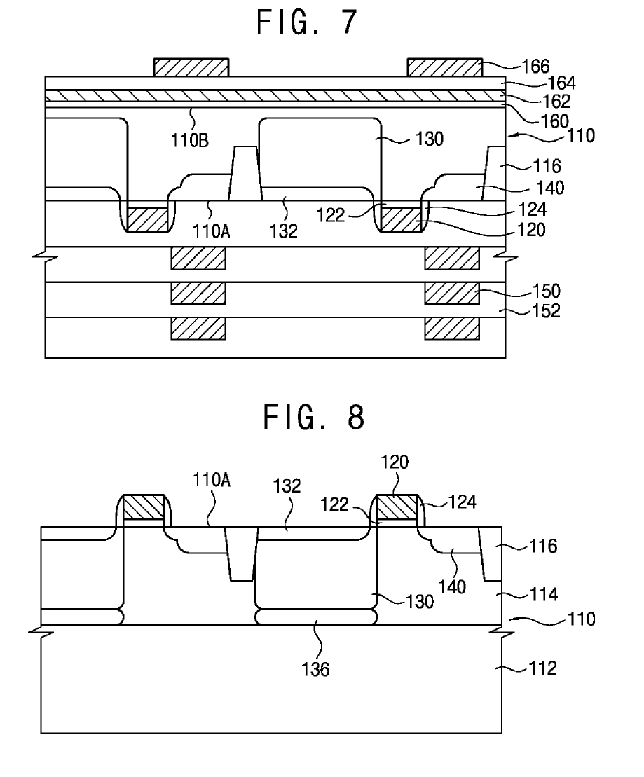

Referring to FIG. 7, an insulating layer 160 may be formed on the backside surface 110B of the substrate 110, and a fixed charge layer 162 may then be formed on the insulating layer 160. The insulating layer 160 may include silicon oxide (SiO₂) or silicon oxynitride (SiON), and the fixed charge layer 162 may include zirconium oxide (ZrO₂), hafnium silicon oxide (HfSiO₂), hafnium silicon oxynitride (HfSiON) or silicon nitride (Si₃N₄), which has positive charges.

Alternatively, when a p-type epitaxial layer and an n-type photodiode are used, a negative fixed charge layer may be formed on the insulating layer 160. The negative fixed charge layer may include hafnium oxide (HfO₂), hafnium oxynitride (HfON), aluminum oxide (Al₂O₃), aluminum oxynitride (AlON), hafnium aluminum oxide (HfAlO) or hafnium aluminum oxynitride (HfAlON), which has negative charges.

A second insulating layer 164 may be formed on the fixed charge layer 162, and light-blocking patterns 166 may then be formed on the second insulating layer 164. The second insulating layer 164 may be made of silicon oxide (SiO₂), and the light-blocking patterns 166 may be made of aluminum (Al), copper (Cu), and the like.

Then, as shown in FIG. 1, a passivation layer 168, a color filter layer 170 and micro lenses 172 may be sequentially formed on the second insulating layer 164 and the light-blocking patterns 166.

FIG. 8 is a cross-sectional view illustrating a method of forming a backside pinning layer as shown in FIG. 2.

Referring to FIG. 8, after forming the gate electrode 120, a backside pinning layer 136 of the first conductive type may be formed in the substrate 110 by an ion implantation process. For example, an n-type backside pinning layer 136 may be formed in the substrate 110 by an ion implantation process.

After forming the n-type backside pinning layer 136, a p-type photodiode 130 may be formed on the n-type backside pinning layer 136 by an ion implantation process, and an n-type frontside pinning layer 132 may be then formed on the p-type photodiode 130 by an ion implantation process. The n-type backside pinning layer 136, the p-type photodiode 130 and the n-type frontside pinning layer 132 may be activated by a rapid thermal process.

The n-type backside pinning layer 136 may be exposed by a back-grinding process. In detail, the back-grinding process may be performed until the n-type backside pinning layer 136 is exposed, and the insulating layer 160 and the fixed charge layer 162 may be sequentially formed on the exposed n-type backside pinning layer 136. That is, the p-type photodiode 130 may be formed on a frontside surface of the n-type backside pinning layer 136, and the insulating layer 160 may be formed on a backside surface of the n-type backside pinning layer 136.

In accordance with exemplary embodiments of the present disclosure as described above, after forming a photodiode 130 in a substrate 110, an insulating layer 160 and a fixed charge layer 162 may be formed on a backside surface 110B of the substrate 110. A charge accumulation region 134 may be formed between the photodiode 130 and the insulating layer 160 by the fixed charge layer 162, which may be used as a backside pinning layer.

As a result, the ion implantation process and the laser annealing process for forming the conventionally used backside pinning layer may be omitted, and the manufacturing cost of the backside illuminated image sensor 100 may thus be significantly reduced.

Further, the thickness of the charge accumulation region 134 may be formed relatively thin, and the size of the photodiode 130 may thus be relatively increased. As a result, the fill factor of the photodiode 130 may be significantly improved.

Although the backside illuminated image sensor and the method of manufacturing the same have been described with reference to specific embodiments, they are not limited thereto. Therefore, it will be readily understood by those skilled in the art that various modifications and changes can be made thereto without departing from the spirit and scope of the present disclosure defined by the appended claims.

Persons of ordinary skill in the relevant arts will recognize that the subject matter hereof may comprise fewer features than illustrated in any individual embodiment described above. The embodiments described herein are not meant to be an exhaustive presentation of the ways in which the various features of the subject matter hereof may be combined. Accordingly, the embodiments are not mutually exclusive combinations of features; rather, the various embodiments can comprise a combination of different individual features selected from different individual embodiments, as understood by persons of ordinary skill in the art. Moreover, elements described with respect to one embodiment can be implemented in other embodiments even when not described in such embodiments unless otherwise noted

Although a dependent claim may refer in the claims to a specific combination with one or more other claims, other embodiments can also include a combination of the dependent claim with the subject matter of each other dependent claim or a combination of one or more features with other dependent or independent claims. Such combinations are proposed herein unless it is stated that a specific combination is not intended.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

For purposes of interpreting the claims, it is expressly intended that the provisions of 35 U.S.C. §112(f) are not to be invoked unless the specific terms “means for” or “step for” are recited in a claim.

1. A backside illuminated image sensor comprising:
a substrate having a frontside surface and a backside surface;
a photodiode disposed in the substrate adjacent the frontside surface;
an insulating layer disposed on the backside surface of the substrate; and
a fixed charge layer disposed on the insulating layer and configured to generate a charge accumulation region between the photodiode and the backside surface.

2. The backside illuminated image sensor of claim 1, further comprising:
a high concentration impurity region disposed in the substrate adjacent the frontside surface and spaced apart from the photodiode; and
a gate electrode disposed on the frontside surface of the substrate between the photodiode and the high concentration impurity region.

3. The backside illuminated image sensor of claim 1, wherein the substrate has a first conductive type and the photodiode has a second conductive type.

4. The backside illuminated image sensor of claim 3, further comprising a frontside pinning layer having the first conductive type and disposed between the photodiode and the frontside surface of the substrate.

5. The backside illuminated image sensor of claim 3, further comprising a backside pinning layer having the first conductive type and disposed between the photodiode and the backside surface of the substrate.

6. A backside illuminated image sensor comprising:
a substrate having a frontside surface and a backside surface;
a p-type photodiode disposed in the substrate adjacent the frontside surface;
an insulating layer disposed on the backside surface of the substrate; and
a positive fixed charge layer disposed on the insulating layer and configured to generate a charge accumulation region between the photodiode and the backside surface.

7. The backside illuminated image sensor of claim 6, further comprising an n-type frontside pinning layer disposed between the p-type photodiode and the frontside surface of the substrate.

8. The backside illuminated image sensor of claim 6, further comprising an n-type backside pinning layer disposed between the p-type photodiode and the backside surface of the substrate.

9. The backside illuminated image sensor of claim 6, further comprising:
a p-type high concentration impurity region disposed in a frontside surface portion of the substrate to be spaced apart from the p-type photodiode; and
a gate electrode disposed on the frontside surface of the substrate between the p-type photodiode and the p-type high concentration impurity region.

10. The backside illuminated image sensor of claim 6, wherein the positive fixed charge layer comprises zirconium oxide, hafnium silicon oxide, hafnium silicon oxynitride or silicon nitride.

11. The backside illuminated image sensor of claim 6, further comprising:
a second insulating layer disposed on the positive fixed charge layer; and
a light-blocking pattern disposed on the second insulating layer.

12. The backside illuminated image sensor of claim 11, further comprising:
a passivation layer disposed on the second insulating layer and the light-blocking pattern;
a color filter layer disposed on the passivation layer; and
a micro lens disposed on the color filter layer.

13. A method of manufacturing a backside illuminated image sensor, the method comprising:
forming a photodiode in a substrate having a frontside surface and a backside surface, wherein the photodiode is formed adjacent the frontside surface;
forming an insulating layer on the backside surface of the substrate; and
forming a fixed charge layer on the insulating layer.

14. The method of claim 13, further comprising:
forming a gate electrode on the frontside surface of the substrate; and
forming a high concentration impurity region in the substrate, the gate electrode being disposed on the frontside surface of the substrate between the photodiode and the high concentration impurity region and configured to selectively electrically interconnect the photodiode and the high concentration impurity region.

15. The method of claim 13, further comprising forming a frontside pinning layer between the photodiode and the frontside surface of the substrate.

16. The method of claim 13, wherein the substrate has a first conductive type and the photodiode has a second conductive type.

17. The method of claim 13, wherein the substrate comprises an n-type epitaxial layer and the photodiode comprises a p-type impurity region formed in the n-type epitaxial layer.

18. The method of claim 17, wherein the fixed charge layer has a positive fixed charge.

19. The method of claim 17, wherein the fixed charge layer comprises zirconium oxide, hafnium silicon oxide, hafnium silicon oxynitride or silicon nitride.

20. The method of claim 13, further comprising:
forming a backside pinning layer in the substrate; and
back-grinding a backside surface portion of the substrate to expose a backside surface of the backside pinning layer,
wherein the photodiode is formed on a frontside surface of the backside pinning layer and the insulating layer is formed on the backside surface of the backside pinning layer.
